(19) United States
(12) Patent Application Publication
(10) Pub. No.: US 2010/0188323 A1
(43) Pub. Date: Jul. 29, 2010

(54) OUTPUT BUFFER AND SOURCE DRIVER USING THEREOF

(75) Inventor: Li-Chun Huang, Yunlin County (TW)

Correspondence Address: RABIN & Berdo, PC, 1101 14TH STREET, NW, SUITE 500, WASHINGTON, DC, 20005, US

(73) Assignee: NOVATEK MICROELECTRONICS CORP., Hsinchu (TW)

(21) Appl. No.: 12/574,055

(22) Filed: Oct. 6, 2009

(30) Foreign Application Priority Data
Jan. 23, 2009 (TW) 098102968

(51) Int. Cl. G09G 5/00; H03K 3/00; G09G 3/36

(52) U.S. Cl. 345/89; 345/211; 327/108

(57) ABSTRACT

An output buffer for providing an output voltage signal includes an operational amplifier, a controller and a power circuit. The operational amplifier provides the output voltage signal according to an input voltage signal. The controller judges whether a reference signal corresponding to the input voltage signal satisfies an energy-saving condition, and triggers an energy-saving operation event if yes, or triggers a normal operation event if not. The power circuit provides an energy-saving power signal to drive the operational amplifier in response to the energy-saving operation event and provides a normal power signal to drive the operational amplifier in response to the normal operation event, such that the operational amplifier provides the output voltage signal according to the input voltage signal. A voltage level of the normal power signal is higher than a voltage level of the energy-saving power signal.

This application claims the benefit of Taiwan application Serial No. 98102968, filed Jan. 23, 2009, the subject matter of which is incorporated herein by reference.

### BACKGROUND OF THE INVENTION

1. Field of the Invention

The invention relates in general to an output buffer, and more particularly to an output buffer capable of selectively adjusting its operation power loss.

2. Description of the Related Art

Generally speaking, the output buffer is applied as an output stage circuit for enhancing the driving ability of an output voltage signal and effectively driving the following loads.

In a source driver of a present liquid crystal display, for example, many output buffers are provided to enhance the driving ability of a pixel voltage signal to be outputted and thus to drive pixels of the liquid crystal display panel.

However, a high-energy power signal is typically provided to the output buffer such that the output buffer has the sufficient driving ability because the output buffer has to enhance the driving ability of the output voltage signal.

In some operation conditions, however, the output buffer is adopted to output the output voltage signal with the lower output level or to drive a load circuit with the lower load. In these examples, most energy in the power signal for driving the output buffer is consumed in the output buffer itself, and only a little portion of the energy is adopted to enhance the driving ability of the output voltage signal. Thus, the conventional output buffer has the drawbacks of the high power consumption and the low electric energy using efficiency.

### SUMMARY OF THE INVENTION

The present invention is directed to an output buffer for selectively selecting a power signal with the higher energy or the lower energy according to a reference signal corresponding to an input voltage signal, and inputting the power signal to the output buffer, such that the output buffer can generate an output voltage signal according to the input voltage signal in a more energy-saving manner. Thus, compared with the conventional output buffer, the output buffer of the invention has the advantages of the lower power consumption and the higher electric energy using efficiency.

According to a first aspect of the present invention, an output buffer for providing an output voltage signal is provided. The output buffer includes an operational amplifier, a controller and a power circuit. The operational amplifier provides the output voltage signal according to an input voltage signal. The controller judges whether a reference signal corresponding to the input voltage signal satisfies an energy-saving condition. The controller triggers an energy-saving operation event when the reference signal satisfies the energy-saving condition, and the controller triggers a normal operation event when the reference signal does not satisfy the energy-saving condition. The power circuit provides an energy-saving power signal to drive the operational amplifier in response to the energy-saving operation event such that the operational amplifier provides the output voltage signal according to the input voltage signal. The power circuit further provides a normal power signal to drive the operational amplifier in response to the normal operation event such that the operational amplifier provides the output voltage signal according to the input voltage signal. A level of the normal power signal is higher than a level of the energy-saving power signal.

According to a second aspect of the present invention, an output buffer for providing an output voltage signal is provided. The output buffer includes an operational amplifier, a controller and first and second power circuits. The operational amplifier provides the output voltage signal according to an input voltage signal. The controller judges whether a reference signal corresponding to the input voltage signal satisfies an energy-saving condition. The controller provides a first control signal when the reference signal satisfies the energy-saving condition, and the controller provides a second control signal when the reference signal does not satisfy the energy-saving condition. The first power circuit is controlled by the first control signal to turn on to provide a first voltage signal to drive the operational amplifier such that the operational amplifier provides the output voltage signal according to the input voltage signal. The second power circuit is controlled by the second control signal to turn on to provide a second voltage signal to drive the operational amplifier such that the operational amplifier provides the output voltage signal according to the input voltage signal. A level of the second voltage signal is higher than a level of the first voltage signal.

According to a third aspect of the present invention, an output buffer for providing an output voltage signal in an operation period is provided. The output buffer includes an operational amplifier, a controller and a power circuit. The operational amplifier provides the output voltage signal according to an input voltage signal. The controller divides the operation period into first and second sub-periods in response to first and second phase control signals. The controller further judges whether a reference signal corresponding to the input voltage signal satisfies the energy-saving condition. When the reference signal satisfies the energy-saving condition, the controller respectively outputs first and second control signals in the first and second sub-periods. The power circuit provides a first voltage signal and a second voltage signal in response to the first and second control signals in the first sub-period and the second sub-period, respectively, to drive the operational amplifier such that the operational amplifier provides the output voltage signal according to the input voltage signal.

According to a fourth aspect of the present invention, a source driver for providing a plurality of pixel voltage signals to drive a liquid crystal display panel is provided. The source driver includes a linear buffer, a digital-to-analog (D/A) converter and multiple output buffers. The linear buffer includes a plurality of linear buffer units for respectively storing a plurality of pieces of input pixel data. The digital-to-analog (D/A) converter includes a plurality of D/A converting units, respectively corresponding to the linear buffer units, for respectively converting the pieces of input pixel data into a plurality of analog voltage signals. Each of the output buffers includes an operational amplifier, a controller and a power circuit. The operational amplifier provides each of the pixel voltage signals according to each of the analog voltage signals. The controller judges whether a reference signal corresponding to each of the analog voltage signals satisfies an energy-saving condition. The controller triggers an energy-saving operation event when the reference signal satisfies the energy-saving condition, and the controller triggers a normal operation event when the reference signal does not satisfy the energy-saving condition. The power circuit provides an energy-saving power signal in response to the energy-saving operation event to drive the operational amplifier such that the operational amplifier provides each of the pixel voltage signals according to each of the analog voltage signals. The power circuit further provides a normal power signal in response to the normal operation event to drive the operational amplifier such that the operational amplifier provides each of the pixel voltage signals according to each of the analog voltage signals. A level of the normal power signal is higher than a level of the energy-saving power signal.

According to a fifth aspect of the present invention, a source driver for providing n pixel voltage signals to drive a liquid crystal display panel is provided, wherein n is a natural number greater than 1. The source driver includes a linear buffer, a digital-to-analog converter and m output buffers, wherein m is a natural number greater than 1. The linear buffer includes n linear buffer units for respectively storing n pieces of input pixel data. The m output buffers respectively provide m gray-level pixel voltage signals corresponding to m gray levels. Each of the m output buffers includes an operational amplifier, a controller and a power circuit. The operational amplifier provides each of the gray-level pixel voltage signals according to a corresponding input voltage signal. The controller judges whether a reference signal corresponding to the input voltage signal satisfies an energy-saving condition. The controller triggers an energy-saving operation event when the reference signal satisfies the energy-saving condition, and the controller triggers a normal operation event when the reference signal does not satisfy the energy-saving condition. The power circuit provides an energy-saving power signal in response to the energy-saving operation event to drive the operational amplifier, such that the operational amplifier provides the gray-level pixel voltage signal according to the input voltage signal. The power circuit further provides a normal power signal to drive the operational amplifier in response to the normal operation event, such that the operational amplifier provides the gray-level pixel voltage signal according to the input voltage signal. A level of the normal power signal is higher than a level of the energy-saving power signal. The digital-to-analog (D/A) converter includes n D/A converting units for respectively selecting at least one gray-level pixel voltages from the m gray-level pixel voltage signals as the n pixel voltage signals for output in response to the n pieces of input pixel data.

The invention will become apparent from the following detailed description of the preferred but non-limiting embodiments. The following description is made with reference to the accompanying drawings.

### BRIEF DESCRIPTION OF THE DRAWINGS

FIG. 1 is a block diagram showing an output buffer according to a first embodiment of the invention.

FIG. 2 is a schematic illustration showing a digital-to-analog converter in the output buffer according to the embodiment of the invention.

FIG. 3 is a detailed block diagram showing the output buffer according to this embodiment of the invention.

FIG. 4 is a graph showing the relationship between an input voltage signal Svi and a reference signal Srf.

FIG. 5 is another block diagram showing the output buffer according to the first embodiment of the invention.

FIG. 6 is a block diagram showing an output buffer according to a second embodiment of the invention.

FIG. 7 is a schematic illustration showing an operation period TP and sub-periods TP_s1 and TP_s2.

FIG. 8 is a block diagram showing a source driver of an output buffer according to the embodiment of the invention.

FIG. 9 is another block diagram showing the source driver of the output buffer according to the embodiment of the invention.

### DETAILED DESCRIPTION OF THE INVENTION

The output buffer of the embodiment selectively drives the output buffer to perform the operation of outputting the voltage signal using the power signal with the lower energy intensity according to a reference signal corresponding to its input voltage signal.

### First Embodiment

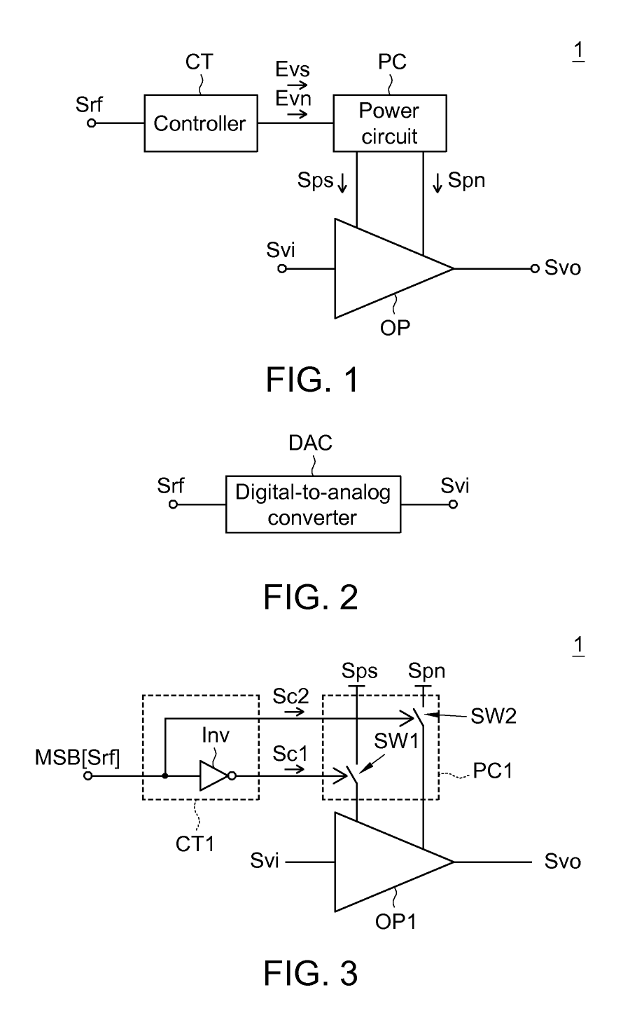

The output buffer of this embodiment selectively adopts one of an energy-saving power signal and a normal power signal as a power signal of an output buffer according to a reference signal corresponding to the input voltage signal. FIG. 1 is a block diagram showing an output buffer 1 according to a first embodiment of the invention. Referring to FIG. 1, the output buffer 1 provides an output voltage signal Svo according to an input voltage signal Svi to drive a load circuit (not shown). The output buffer 1 includes an operational amplifier OP, a controller CT and a power circuit PC.

The operational amplifier OP receives the input voltage signal Svi and correspondingly provides the output voltage signal Svo. The controller CT judges whether a reference signal Srf corresponding to the input voltage signal Svi satisfies an energy-saving condition. For example, the reference signal Srf may be digital voltage data corresponding to the input voltage signal Svi. In one example, the reference signal Srf is a 6-bit digital voltage signal, while the input voltage signal Svi is obtained after a digital-to-analog converter DAC has converted the reference signal Srf, as shown in FIG. 2.

The controller CT judges that the reference signal Srf satisfies the energy-saving condition when a data value corresponding to the reference signal Srf is smaller than a reference signal threshold value, and judges that the reference signal does not satisfy energy-saving condition when the data value corresponding to the reference signal Srf is greater than or equal to the reference signal threshold value.

When the reference signal Srf satisfies the energy-saving condition, the operational amplifier OP does not need the supply of the higher power voltage. Thus, the controller CT triggers an energy-saving operation event Evs such that the power circuit PC provides an energy-saving power signal Sps to drive the operational amplifier OP in response to the energy-saving operation event Evs, and the operational amplifier OP provides the output voltage signal Svo to drive the load circuit according to the input voltage signal Svi.

When then reference signal Srf does not satisfy the energy-saving condition, the controller CT triggers a normal operation event Evn such that the power circuit PC provides a normal power signal Spn to drive the operational amplifier OP in response to the normal operation event Evn such that the operational amplifier OP provides the output voltage signal Svo to drive the load circuit according to the input voltage signal Svi. A corresponding level of the normal power signal Spn is higher than that of the energy-saving power signal Sps.

FIG. 3 is a detailed block diagram showing the output buffer according to this embodiment of the invention. The controller CT1 includes an inverter Inv for receiving a most significant bit MSB[Srf] of the reference signal Srf, and the reference signal threshold value is 32 (i.e., (100000)₂). When the MSB[Srf] is the value 0, it represents that the signal value of the reference signal Srf is smaller than the value 32 (i.e., the reference signal threshold value). At this time, the controller CT1 provides an enabled control signal Sc1 to trigger the energy-saving operation event Evs. When MSB[Srf] is the value 1, it represents that the signal value of the reference signal Srf is greater than or equal to the value 32 (i.e., the reference signal threshold value). At this time, the controller CT1 provides an enabled control signal Sc2 to trigger the normal operation event Evn.

The power circuit PC1 includes power switches SW1 and SW2 having first terminals respectively receiving the energy-saving power signal Sps and the normal power signal Spn, and second terminals coupled to the operational amplifier OP1. When the energy-saving operation event Evs is triggered, the power switch SW1 controlled by the enabled control signal Sc1 turns on to provide the energy-saving power signal Sps to the operational amplifier OP1, and the power switch SW1 controlled by the disabled control signal Sc2 to turn off. Thus, the operational amplifier OP1 can receive the power signal Sps with the lower level to output the output voltage signal Svo with the higher driving ability to the next stage of load circuits according to the input voltage signal Svi.

On the other hand, when the normal operation event Evn is triggered, the power switch SW2 controlled by the enabled control signal Sc2 turns on to provide the normal power signal Spn to the operational amplifier OP1, and the power switch SW2 controlled by the disabled control signal Sc1 turns off. Thus, the operational amplifier OP1 can receive the power signal Spn with the higher level to output the output voltage signal Svo with the higher driving ability to the next stage of load circuits according to the input voltage signal Svi.

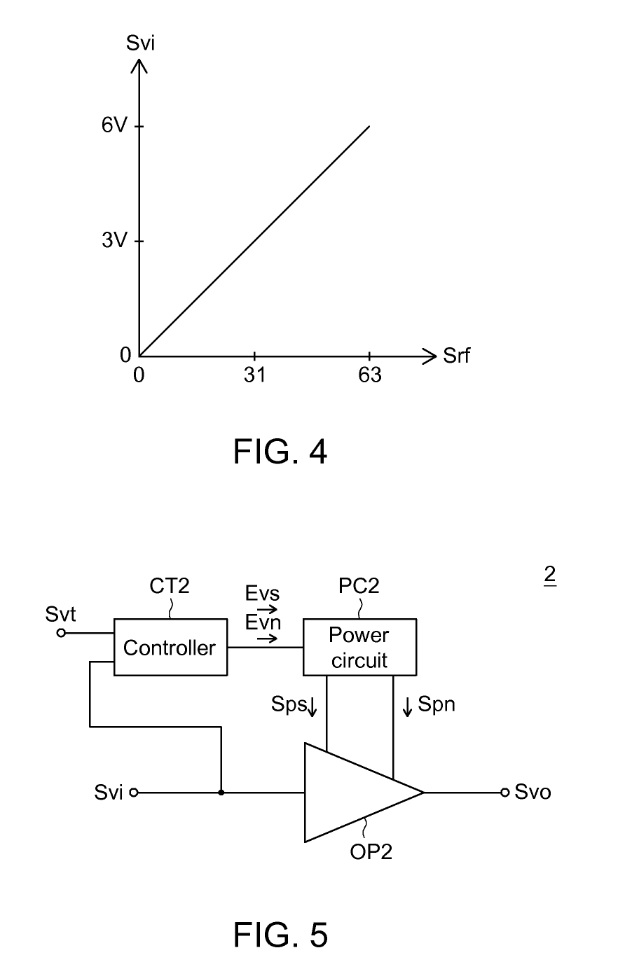

FIG. 4 is a graph showing the relationship between the input voltage signal Svi and the reference signal Srf. For example, the reference signal Srf and the input voltage signal Svi have the linear relationship, as shown in FIG. 4. In one example, when the signal value corresponding to the reference signal Srf is greater than or equal to 32, the power circuit PC1 provides the normal power signal Spn with the voltage level of 6 volts to drive the operational amplifier OP1. When the signal value corresponding to the reference signal Srf is smaller than 32, the power circuit PC1 provides the energy-saving power signal Sps with the voltage level of 3V to drive the operational amplifier OP1.

In this illustrated embodiment, the controller CT judges whether it satisfies one energy-saving condition according to the reference signal Srf, and thus triggers two different operation events (energy-saving operation event Evs and normal operation event Evn). However, the controller CT of this embodiment is not limited thereto. In other examples, the controller may also judge whether it satisfies two or more than two judgement conditions according to the reference signal Srf, and thus trigger three or more than three operation events. The power circuit of this embodiment may also correspondingly drive the power circuit to provide three or more that three energy signals, corresponding to different energy intensities, to the operational amplifier in response to three or more than three operation events triggered by the controller. The corresponding modification is also regarded as falling within the scope of the invention.

In this illustrated embodiment, the controller CT1 is implemented by the inverter Inv to trigger the energy-saving operation event Evs and the normal operation event Evn according to the MSB[Srf] of the reference signal Srf. However, the controller CT1 of this embodiment is not limited thereto. In other example, the controller may include a programmable logic circuit for performing other logic operations in response to an input program code to trigger the energy-saving operation event Evs and the normal operation event Evn according to the reference signal Srf.

In this embodiment, the invention utilizes the reference signal Srf as the basis for triggering the energy-saving operation event Evs and the normal operation event Evn. However, the invention is not limited thereto. In other embodiments, the invention may also adopt other signals associated with the input voltage signal Svi, such as the analog voltage signal corresponding to the input voltage signal Svi.

For example, the invention may directly utilize the input voltage signal Svi as the reference signal Srf. That is, the controller CT2 directly triggers the energy-saving operation event Evs and the normal operation event Evn according to the input voltage signal Svi, as shown in FIG. 5. The controller CT2 includes, for example, a comparator for judging whether the level of the reference signal (i.e., the input voltage signal Svi) is higher than the level of a threshold voltage signal Svt through the analog voltage comparison operation. When the level of the reference signal is lower than the level of the threshold voltage signal Svt, the controller CT2 judges that the reference signal satisfies the energy-saving condition to trigger the energy-saving operation event Evs such that the power circuit PC2 provides the power Sps with the lower level to the operational amplifier OP. When the level of the reference signal is greater than or equal to the level of the threshold voltage signal Svt, the controller CT2 judges that the reference signal does not satisfy the energy-saving condition to trigger the normal operation event Evn such that the power circuit PC2 provides the power Spn with the higher level to the operational amplifier OP.

In this illustrated embodiment, the reference signal Srf and the input voltage signal Svi have the linear relationship. However, the reference signal Srf and the input voltage signal Svi of this embodiment are not limited thereto. In other examples, the reference signal Srf and the input voltage signal Svi may also relate to each other via other mathematical relationships, or the circuit designer may choose the relationship therebetween. Such correspondingly modifications are also regarded as falling within the scope of the invention.

In this illustrated embodiment, the energy-saving power signal Sps and the normal power signal Spn respectively have the voltage levels of 3V and 6V. However, the energy-saving power signal Sps and the normal power signal Spn of this embodiment are not limited thereto. In other examples, the levels of the energy-saving power signal Sps and the normal power signal Spn may also be flexibly adjusted according to the level of the input voltage signal Svi, the relationships between the level of the input voltage signal Svi and the level of the reference signal Srf, and the actual circuit applications, such as the load circuit.

The output buffer of this embodiment selectively adopts one of the energy-saving power signal and the normal power signal as the power signal of the output buffer according to the reference signal corresponding to the input voltage signal. Thus, the output buffer of this embodiment may selectively select the energy signal corresponding to the higher energy or the energy signal corresponding to the lower energy according to the reference signal, corresponding to the input voltage signal, to perform the operation of generating the output voltage signal according to the input voltage signal. Consequently, compared with the conventional output buffer, the output buffer of the invention has the advantages of the lower power consumption and the higher electric energy using efficiency.

### Second Embodiment

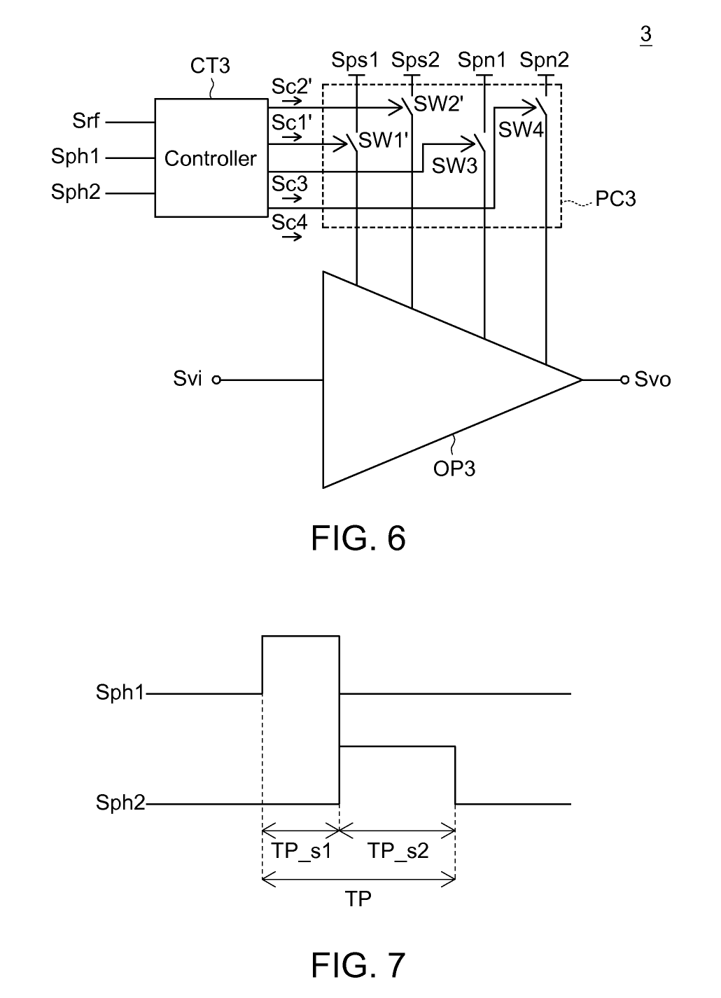

The controller of the output buffer of this embodiment is controlled by the first phase control signal and the second phase control signal to divide the operation period into a first sub-period and a second sub-period, and drives the operational amplifiers of the output buffer in a time-division multiplexing manner. FIG. 6 is a block diagram showing an output buffer 3 according to a second embodiment of the invention. The difference between the output buffer 3 of this embodiment and the output buffer of the first embodiment resides in that the controller CT3 receives the phase control signals Sph1 and Sph2 to divide the operation period TP, according to which the output buffer 3 works according to the input voltage signal Svi and the output voltage signal Svo, into sub-periods TP_s1 and TP_s2, as shown in FIG. 7.

In one example, the power circuit PC3 includes power switches SW1′ and SW2′. When the reference signal Srf satisfies the energy-saving condition, the controller CT2 respectively outputs the control signals Sc1′ and Sc2′ in the sub-periods TP_s1 and TP_S2 to trigger the energy-saving operation event. The control signal Sc1′ turns on the power switch SW1′ in the sub-period TP_s1 to provide an energy-saving power signal Sps1 to drive the operational amplifier OP3. The control signal Sc2′ turns on the power switch SW2′ in the sub-period TP_s2 to provide an energy-saving power signal Sps2 to drive the operational amplifier OP3. Thus, the operational amplifier OP3 is driven in the time-division multiplexing manner.

For example, the voltage level of the energy-saving power signal Sps1 is lower than the level to be reached by the output voltage signal Svo, and the level of the energy-saving power signal Sps2 is higher than or equal to the level to be reached by the output voltage signal Svo. Thus, the operational amplifier OP3 may be driven by the power signal Sps1 with the lower level to provide the lower driving ability to pre-charge the load circuit. Thereafter, the power signal Sps2 with the higher level is adopted to drive the operational amplifier OP3 to provide the higher driving ability to drive the load circuit. Thus, the speed of charging the load circuit by the output buffer 3 may be increased. In addition, because the power signal with the lower level drives the operational amplifier OP3 in the sub-period TP_μl, the power consumption of the output buffer 3 may be decreased as a whole.

In one example, the power circuit PC3 further includes power switches SW3 and SW4. Similar to the operation when the reference signal Srf satisfies the energy-saving condition, when the reference signal Srf does not satisfy the energy-saving condition, the controller CT2 respectively outputs control signals Sc3 and Sc4 in the sub-periods TP_s1 and TP_S2 to trigger the normal operation event. The control signal Sc3 turns on the power switch SW3 in the sub-period TP_s1 to provide the normal power signal Spn1 to drive the operational amplifier OP3. The control signal Sc4 turns on the power switch SW4 in the sub-period TP_s2 to provide the normal power signal Spn2 to drive the operational amplifier OP3. Thus, when the reference signal Srf does not satisfy the energy-saving condition, the output buffer 3 may also drive the operational amplifier OP3 in a time-division multiplexing manner to increase the speed of charging the load circuit by the output buffer 3 and reduce its power consumption.

In this illustrated embodiment, the energy-saving power signals Sps1 and Sps2 are provided to drive the operational amplifier OP3 when the reference signal Srf satisfies the energy-saving condition, and the normal power signals Spn1 and Spn2 are provided to drive the operational amplifier OP3 when the reference signal Srf does not satisfy the energy-saving condition. However, the output buffer 3 of this embodiment is not limited thereto. In other examples, the output buffer OP3 may also have only one energy-saving power signal and one normal power signal. The output buffer OP3 may also have different driving abilities by determining the lengths of the sub-periods, during which the energy-saving power signal and the normal power signal are utilized to drive the operational amplifier OP3.

The controller in the output buffer of this embodiment is controlled by the first and second phase control signals to divide the operation period into a first sub-period and a second sub-period to perform the time-division multiplex control on the operational amplifiers in the output buffer. Thus, compared with the conventional output buffer, the output buffer of the invention has the advantages of the lower power consumption and the higher electric energy using efficiency.

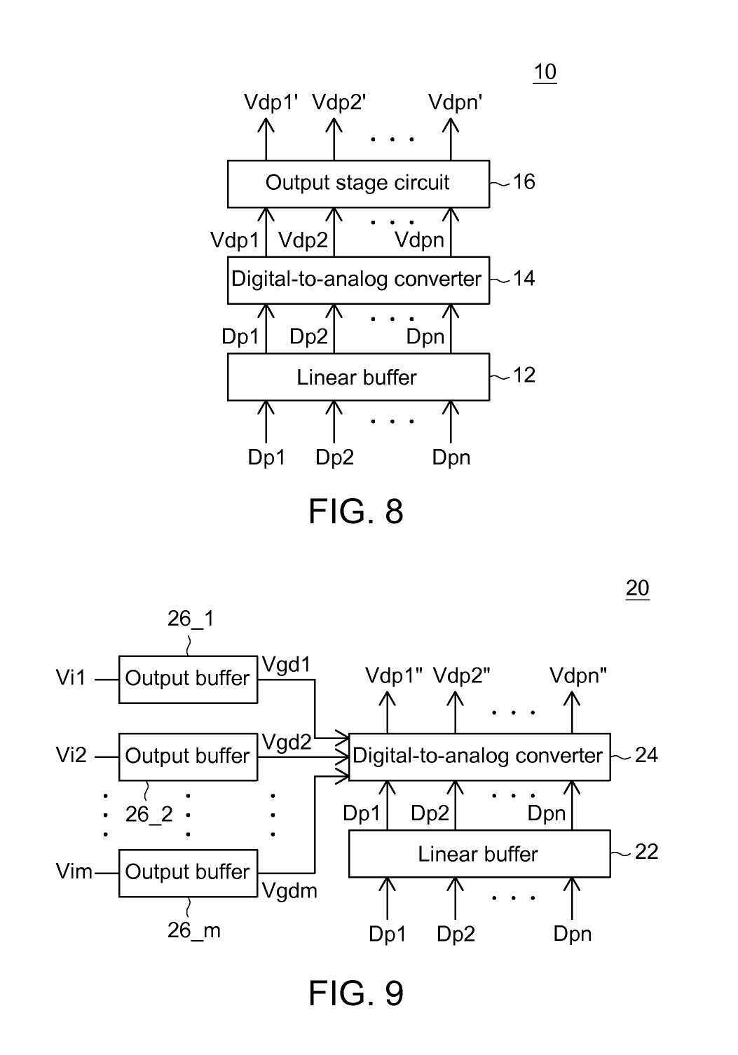

In one example, the output buffer according to the embodiment of the invention may be applied to a source driver 10 to provide n pixel voltage signals Vdp1′, Vdp2′, . . . , Vdpn′, as shown in FIG. 8, wherein n is a natural number greater than 1. The source driver 10 includes a linear buffer 12, a D/A converter 14 and an output stage circuit 16. The linear buffer 12 includes n buffer units (not shown) for respectively receiving and temporarily storing n pieces of pixel data Dp1, Dp2, . . . , Dpn. The D/A converter 14 includes n D/A units (not shown) for respectively converting the pixel data Dp1 to Dpn into n pieces of analog voltage signals Vdp1, Vdp2, . . . , Vdpn, wherein n is a natural number greater than 1.

The output stage circuit 16 includes n output buffers (not shown), which respectively adopts the n analog voltage signals Vdp1 to Vdpn as the input signals to provide the corresponding n pixel voltage signals Vdp1′ to Vdpn′.

In another example, the output buffer according to the embodiment of the invention may be applied to a source driver 20 according to another aspect of the invention, as shown in FIG. 9. The source driver 20 includes a linear buffer 22, a D/A converter 24 and m output buffers 26_{—}1, 26_2, . . . , 26_m, wherein m is a natural number greater than 1. The linear buffer 22 includes n buffer units (not shown) for respectively receiving and temporarily storing n pieces of pixel data Dp1, Dp2, . . . , Dpn.

The output buffers 26_1 to 26_m respectively receive m input analog voltage signals Vi1, Vi2, . . . , Vim corresponding to m gray levels, and thus provides m gray-level pixel voltage signals Vgd1, Vgd2, . . . , Vgdm respectively corresponding to m gray levels. The D/A converter 24 includes n D/A units (not shown). Each of the n D/A units selects one of the m gray-level pixel voltage signals Vgd1 to Vgdm as the corresponding pixel voltage signal for output according to the gray level corresponding to each of the n pieces of pixel data Dp1 to Dpn.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An output buffer for providing an output voltage signal, the output buffer comprising:
an operational amplifier for providing the output voltage signal according to an input voltage signal;
a controller for judging whether a reference signal corresponding to the input voltage signal satisfies an energy-saving condition, wherein the controller triggers an energy-saving operation event when the reference signal satisfies the energy-saving condition, and the controller triggers a normal operation event when the reference signal does not satisfy the energy-saving condition; and
a power circuit for providing an energy-saving power signal to drive the operational amplifier in response to the energy-saving operation event, such that the operational amplifier provides the output voltage signal according to the input voltage signal, wherein the power circuit further provides a normal power signal to drive the operational amplifier in response to the normal operation event, such that the operational amplifier provides the output voltage signal according to the input voltage signal, wherein a level of the normal power signal is higher than a level of the energy-saving power signal.

2. The output buffer according to claim 1, wherein the reference signal is digital voltage data corresponding to the input voltage signal, and the controller judges that the reference signal satisfies the energy-saving condition when the digital voltage data is smaller than a threshold value.

3. The output buffer according to claim 2, wherein the controller judges whether the digital voltage data is smaller than the threshold value according to a value of a most significant bit (MSB) of the digital voltage data.

4. The output buffer according to claim 1, wherein the reference signal is an analog voltage signal corresponding to the input voltage signal, and the controller judges that the reference signal satisfies the energy-saving condition when a level of the analog voltage signal is lower than a threshold voltage.

5. The output buffer according to claim 1, wherein:
when the reference signal satisfies the energy-saving condition, the controller outputs a first control signal in an operation period to trigger the energy-saving operation event; and
the power circuit controlled by the first control signal provides a first voltage signal as the energy-saving power signal to drive the operational amplifier, such that the operational amplifier provides the output voltage signal according to the input voltage signal.

6. The output buffer according to claim 5, wherein:
when the reference signal does not satisfy the energy-saving condition, the controller outputs a second control signal in the operation period to trigger the normal operation event;
the power circuit controlled by the second control signal provides a second voltage signal as the normal power signal to drive the operational amplifier, such that the operational amplifier provides the output voltage signal according to the input voltage signal; and
a level of the first voltage signal is lower than a level of the second voltage signal.

7. The output buffer according to claim 1, wherein:
the controller further divides an operation period into a first sub-period and a second sub-period in response to a first phase control signal and a second phase control signal;
when the reference signal satisfies the energy-saving condition, the controller respectively outputs a first control signal and a second control signal in the first sub-period and the second sub-period to trigger the energy-saving operation event; and
the power circuit controlled by the first and second control signals provide a first voltage signal and a second voltage signal in the first and second sub-periods, respectively, to drive the operational amplifier, such that the operational amplifier provides the output voltage signal according to the input voltage signal.

8. The output buffer according to claim 1, wherein:
the controller further divides an operation period into a first sub-period and a second sub-period in response to a first phase control signal and a second phase control signal;
when the reference signal does not satisfy the energy-saving condition, the controller respectively outputs a third control signal and a fourth control signal in the first sub-period and the second sub-period to trigger the normal operation event; and
the power circuit controlled by the third and fourth control signals provides a third voltage signal and a fourth voltage signal in the first and second sub-periods, respectively, to drive the operational amplifier, such that the operational amplifier provides the output voltage signal according to the input voltage signal.

9. An output buffer for providing an output voltage signal, the output buffer comprising:
an operational amplifier for providing the output voltage signal according to an input voltage signal;
a controller for judging whether a reference signal corresponding to the input voltage signal satisfies an energy-saving condition, wherein the controller provides a first control signal when the reference signal satisfies the energy-saving condition, and the controller provides a second control signal when the reference signal does not satisfy the energy-saving condition;
a first power circuit controlled by the first control signal to be turned on, so as to provide a first voltage signal to drive the operational amplifier, such that the operational amplifier provides the output voltage signal according to the input voltage signal; and
a second power circuit controlled by the second control signal to be turned on, so as to provide a second voltage signal to drive the operational amplifier, such that the operational amplifier provides the output voltage signal according to the input voltage signal, wherein a level of the second voltage signal is higher than a level of the first voltage signal.

10. The output buffer according to claim 9, wherein the reference signal is digital voltage data corresponding to the input voltage signal, and the controller judges that the reference signal satisfies the energy-saving condition when the digital voltage data is smaller than a threshold value, and judges that the reference signal does not satisfy the energy-saving condition when the digital voltage data is greater than or equal to the threshold value.

11. The output buffer according to claim 10, wherein the controller judges whether the digital voltage data is smaller than the threshold value according to a value of a most significant bit (MSB) of the digital voltage data.

12. The output buffer according to claim 9, wherein the reference signal is an analog voltage signal corresponding to the input voltage signal, and the controller judges that the reference signal satisfies the energy-saving condition when a level of the analog voltage signal is lower than a threshold voltage, and judges that the reference signal does not satisfy the energy-saving condition when the level of the analog voltage signal is greater than or equal to the threshold voltage.

13. An output buffer for providing an output voltage signal in an operation period, the output buffer comprising:
an operational amplifier for providing the output voltage signal according to an input voltage signal;
a controller for dividing the operation period into a first sub-period and a second sub-period in response to a first phase control signal and a second phase control signal, wherein the controller further respectively outputs a first control signal and a second control signal in the first sub-period and the second sub-period; and
a power circuit for providing a first voltage signal and a second voltage signal in response to the first and second control signals in the first sub-period and the second sub-period, respectively, to drive the operational amplifier, such that the operational amplifier provides the output voltage signal according to the input voltage signal.

14. The output buffer according to claim 13, wherein the controller further judges whether a reference signal corresponding to the input voltage signal satisfies an energy-saving condition, and the controller respectively outputs the first control signal and the second control signal in the first sub-period and the second sub-period when the reference signal satisfies the energy-saving condition.

15. The output buffer according to claim 14, wherein the reference signal is digital voltage data corresponding to the input voltage signal, and the controller judges that the reference signal satisfies the energy-saving condition when the digital voltage data is smaller than a threshold value.

16. The output buffer according to claim 15, wherein the controller judges whether the digital voltage data is smaller than the threshold value according to a value of a most significant bit (MSB) of the digital voltage data.

17. The output buffer according to claim 14, wherein the reference signal is an analog voltage signal corresponding to the input voltage signal, and the controller judges that the reference signal satisfies the energy-saving condition when a level of the analog voltage signal is lower than a threshold voltage.

18. The output buffer according to claim 13, wherein:
the controller further judges whether a reference signal corresponding to the input voltage signal satisfies an energy-saving condition, and the controller respectively outputs the first control signal and the second control signal in the first sub-period and the second sub-period when the reference signal does not satisfy the energy-saving condition; and
the power circuit provides a third voltage signal and a fourth voltage signal in response to the first and second control signals in the first sub-period and the second sub-period, respectively, to drive the operational amplifier, such that the operational amplifier provides the output voltage signal according to the input voltage signal.

19. A source driver for providing a plurality of pixel voltage signals to drive a liquid crystal display panel, the source driver comprising:
a linear buffer comprising a plurality of linear buffer units for respectively storing a plurality of pieces of input pixel data;
a digital-to-analog (D/A) converter comprising a plurality of D/A converting units, respectively corresponding to the linear buffer units, for respectively converting the pieces of input pixel data into a plurality of analog voltage signals; and
a plurality of output buffers each comprising:
an operational amplifier for providing each of the pixel voltage signals according to each of the analog voltage signals;
a controller for judging whether a reference signal corresponding to each of the analog voltage signals satisfies an energy-saving condition, wherein the controller triggers an energy-saving operation event when the reference signal satisfies the energy-saving condition, and the controller triggers a normal operation event when the reference signal does not satisfy the energy-saving condition; and
a power circuit for providing an energy-saving power signal in response to the energy-saving operation event to drive the operational amplifier, such that the operational amplifier provides each of the pixel voltage signals according to each of the analog voltage signals, wherein the power circuit further provides a normal power signal in response to the normal operation event to drive the operational amplifier, such that the operational amplifier provides each of the pixel voltage signals according to each of the analog voltage signals, wherein a level of the normal power signal is higher than a level of the energy-saving power signal.

20. The source driver according to claim 19, wherein the reference signal corresponds to the input pixel data, and the controller judges that the reference signal satisfies the energy-saving condition when the input pixel data is smaller than a threshold value, and judges that the reference signal does not satisfy the energy-saving condition when the input pixel data is greater than or equal to the threshold value.

21. The source driver according to claim 20, wherein the controller judges whether digital voltage data is smaller than the threshold value according to a value of a most significant bit (MSB) of the digital voltage data.

22. The source driver according to claim 19, wherein the reference signal corresponds to the analog voltage signal, and the controller judges that the reference signal satisfies the energy-saving condition when a level of the analog voltage signal is smaller than a threshold voltage.

23. The source driver according to claim 19, wherein:
when the reference signal satisfies the energy-saving condition, the controller outputs a first control signal in an operation period to trigger the energy-saving operation event; and
the power circuit controlled by the first control signal provides a first voltage signal as the energy-saving power signal to drive the operational amplifier, such that the operational amplifier provides each of the pixel voltage signals according to each of the analog voltage signals.

24. The source driver according to claim 23, wherein:
when the reference signal does not satisfy the energy-saving condition, the controller outputs a second control signal in the operation period to trigger the normal operation event;
the power circuit controlled by the second control signal provides a second voltage signal as the energy-saving power signal to drive the operational amplifier, such that the operational amplifier provides each of the pixel voltage signals according to each of the analog voltage signals; and
a level of the first voltage signal is lower than a level of the second voltage signal.

25. The source driver according to claim 19, wherein:
the controller further divides an operation period into a first sub-period and a second sub-period in response to a first phase control signal and a second phase control signal;
when the reference signal satisfies the energy-saving condition, the controller respectively outputs a first control signal and a second control signal in the first sub-period and the second sub-period to trigger the energy-saving operation event; and
the power circuit controlled by the first and second control signals provides a first voltage signal and a second voltage signal in the first and second sub-periods, respectively, to drive the operational amplifier, such that the operational amplifier provides each of the pixel voltage signals according to each of the analog voltage signals.

26. The source driver according to claim 19, wherein:
the controller further divides an operation period into a first sub-period and a second sub-period in response to a first phase control signal and a second phase control signal;
when the reference signal does not satisfy the energy-saving condition, the controller respectively outputs a third control signal and a fourth control signal in the first sub-period and the second sub-period to trigger the normal operation event; and
the power circuit controlled by the third and fourth control signals provides a third voltage signal and a fourth voltage signal in the first and second sub-periods, respectively, to drive the operational amplifier, such that the operational amplifier provides each of the pixel voltage signals according to each of the analog voltage signals.

27. A source driver for providing n pixel voltage signals to drive a liquid crystal display panel, n being a natural number greater than 1, the source driver comprising:
a linear buffer comprising n linear buffer units for respectively storing n pieces of input pixel data;
m output buffers for respectively providing m gray-level pixel voltage signals corresponding to m gray levels, wherein m is a natural number greater than 1, and each of the output buffers comprises:
an operational amplifier for providing each of the gray-level pixel voltage signals according to a corresponding input voltage signal;
a controller for judging whether a reference signal corresponding to the input voltage signal satisfies an energy-saving condition, wherein the controller triggers an energy-saving operation event when the reference signal satisfies the energy-saving condition, and the controller triggers a normal operation event when the reference signal does not satisfy the energy-saving condition; and
a power circuit for providing an energy-saving power signal in response to the energy-saving operation event to drive the operational amplifier, such that the operational amplifier provides the gray-level pixel voltage signal according to the input voltage signal, and the power circuit further provides a normal power signal to drive the operational amplifier in response to the normal operation event, such that the operational amplifier provides the gray-level pixel voltage signal according to the input voltage signal, wherein a level of the normal power signal is higher than a level of the energy-saving power signal; and
a digital-to-analog (D/A) converter comprising n D/A converting units for respectively selecting at least one gray-level pixel voltage from the m gray-level pixel voltage signals as the n pixel voltage signals for output in response to the n pieces of input pixel data.

28. The source driver according to claim 27, wherein the reference signal is digital voltage data corresponding to the input voltage signal, and the controller judges that the reference signal satisfies the energy-saving condition when the digital voltage data is smaller than a threshold value.

29. The source driver according to claim 28, wherein the controller judges whether the digital voltage data is smaller than the threshold value according to a value of a most significant bit (MSB) of the digital voltage data.

30. The source driver according to claim 27, wherein the reference signal is an analog voltage signal corresponding to the input voltage signal, and the controller judges that the reference signal satisfies the energy-saving condition when a level of the analog voltage signal is lower than a threshold voltage, and judges that the reference signal does not satisfy the energy-saving condition when the level of the analog voltage signal is greater than or equal to the threshold voltage.

31. The source driver according to claim 27, wherein:
when the reference signal satisfies the energy-saving condition, the controller outputs a first control signal in an operation period to trigger the energy-saving operation event; and
the power circuit controlled by the first control signal provides a first voltage signal as the energy-saving power signal to drive the operational amplifier, such that the operational amplifier provides each of the gray-level pixel voltage signals according to the corresponding input voltage signal.

32. The source driver according to claim 31, wherein:
when the reference signal does not satisfy the energy-saving condition, the controller outputs a second control signal in the operation period to trigger the normal operation event;
the power circuit controlled by the second control signal provides a second voltage signal as the energy-saving power signal to drive the operational amplifier, such that the operational amplifier provides each of the gray-level pixel voltage signals according to the corresponding input voltage signal; and
a level of the first voltage signal is lower than a level of the second voltage signal.

33. The source driver according to claim 27, wherein:
the controller further divides an operation period into a first sub-period and a second sub-period in response to a first phase control signal and a second phase control signal;
when the reference signal satisfies the energy-saving condition, the controller respectively outputs a first control signal and a second control signal in the first sub-period and the second sub-period to trigger the energy-saving operation event; and
the power circuit controlled by the first and second control signals provides a first voltage signal and a second voltage signal in the first and second sub-periods, respectively, to drive the operational amplifier, such that the operational amplifier provides each of the gray-level pixel voltage signals according to the corresponding input voltage signal.

34. The source driver according to claim 27, wherein:
the controller further divides an operation period into a first sub-period and a second sub-period in response to a first phase control signal and a second phase control signal;
when the reference signal does not satisfy the energy-saving condition, the controller respectively outputs a third control signal and a fourth control signal in the first sub-period and the second sub-period to trigger the normal operation event; and
the power circuit controlled by the third and fourth control signals provides a third voltage signal and a fourth voltage signal, respectively, to drive the operational amplifier in the first and second sub-periods, such that the operational amplifier provides each of the gray-level pixel voltage signals according to the corresponding input voltage signal.

35. An output buffer for providing an output voltage signal in an operation period, the output buffer comprising:
an operational amplifier for providing the output voltage signal according to an input voltage signal; and
a power circuit, coupled to the operational amplifier, for selectively providing a first power voltage or a second power voltage to the operational amplifier according to a reference signal,
wherein the reference signal corresponds to the input voltage signal.

36. The output buffer according to claim 35, further comprising:
a controller for outputting a first control signal according to an energy-saving condition indicated by the reference signal in the operation period, and outputting a second control signal according to a normal condition indicated by the reference signal in the operation period,
wherein the power circuit is controlled by the first control signal to provide the first power voltage to drive the operational amplifier, and is controlled by the second control signal to provide the second power voltage to drive the operational amplifier, such that the operational amplifier provides the output voltage signal according to the input voltage signal.

37. The output buffer according to claim 35, further comprising:
a controller for dividing the operation period into a first sub-period and a second sub-period in response to a first phase control signal and a second phase control signal, wherein the controller respectively outputs a first control signal and a second control signal in the first and the second sub-periods according to an energy-saving condition indicated by the reference signal,
wherein the power circuit controlled by the first and second control signals provides a first voltage signal and a second voltage signal in the first and second sub-periods, respectively, to drive the operational amplifier, such that the operational amplifier provides the output voltage signal according to the input voltage signal.

38. The output buffer according to claim 37, wherein
the controller respectively outputs a third control signal and a fourth control signal in the first and the second sub-periods according to a normal condition indicated by the reference signal; and
the power circuit controlled by the third and the fourth control signals provides a third voltage signal and a fourth voltage signal in the first and second sub-periods, respectively, to drive the operational amplifier, such that the operational amplifier provides the output voltage signal according to the input voltage signal.

39. A source driver for providing a plurality of pixel voltage signals to drive a liquid crystal display panel, the source driver comprising:
a linear buffer comprising a plurality of linear buffer units for respectively storing a plurality of pieces of input pixel data;
a digital-to-analog (D/A) converter comprising a plurality of D/A converting units respectively corresponding to the linear buffer units to convert the pieces of input pixel data into a plurality of analog voltage signals, respectively; and
a plurality of output buffers each comprising:
an operational amplifier for providing an output voltage signal according to an input voltage signal; and
a power circuit, coupled to the operational amplifier, for selectively providing a first power voltage or a second power voltage to the operational amplifier according to a reference signal,
wherein the reference signal corresponds to the input voltage signal.

40. The source driver according to claim 39, further comprising:
a controller for outputting a first control signal according to an energy-saving condition indicated by the reference signal in an operation period, and outputting a second control signal according to a normal condition indicated by the reference signal in the operation period,
wherein the power circuit is controlled by the first control signal to provide the first power voltage to drive the operational amplifier, and is controlled by the second control signal to provide the second power voltage to drive the operational amplifier, such that the operational amplifier provides the output voltage signal according to the input voltage signal.

41. The source driver according to claim 39, further comprising:
a controller for dividing an operation period into a first sub-period and a second sub-period in response to a first phase control signal and a second phase control signal, wherein the controller respectively outputs a first control signal and a second control signal in the first and second sub-periods according to an energy-saving condition indicated by the reference signal,
wherein the power circuit controlled by the first and second control signals provides a first voltage signal and a second voltage signal in the first and second sub-periods, respectively, to drive the operational amplifier, such that the operational amplifier provides the output voltage signal according to the input voltage signal.

42. The source driver according to claim 41, wherein:
the controller respectively outputs a third control signal and a fourth control signal in the first and the second sub-periods according to a normal condition indicated by the reference signal; and
the power circuit controlled by the third and the fourth control signals provides a third voltage signal and a fourth voltage signal in the first and second sub-periods, respectively, to drive the operational amplifier, such that the operational amplifier provides the output voltage signal according to the input voltage signal.

43. A source driver for providing n pixel voltage signals to drive a liquid crystal display panel, n being a natural number greater than 1, the source driver comprising:
a linear buffer comprising n linear buffer units for respectively storing n pieces of input pixel data;
m output buffers for respectively providing m gray-level pixel voltage signals corresponding to m gray levels, wherein m is a natural number greater than 1, and each of the output buffers comprises:
an operational amplifier for providing an output voltage signal according to an input voltage signal; and
a power circuit, coupled to the operational amplifier, for selectively providing a first power voltage or a second power voltage to the operational amplifier according to a reference signal; and
a digital-to-analog (D/A) converter comprising n D/A converting units for selecting at least one gray-level pixel voltage from the m gray-level pixel voltage signals as the n pixel voltage signals for output in response to the n pieces of input pixel data,
wherein the reference signal corresponds to the input voltage signal.

44. The source driver according to claim 43, further comprising:
a controller for outputting a first control signal according to an energy-saving condition indicated by the reference signal in an operation period, and outputting a second control signal according to a normal condition indicated by the reference signal in the operation period,
wherein the power circuit is controlled by the first control signal to provide the first power voltage to drive the operational amplifier, and is controlled by the second control signal to provide the second power voltage to drive the operational amplifier, such that the operational amplifier provides the output voltage signal according to the input voltage signal.

45. The source driver according to claim 43, further comprising:
a controller for dividing an operation period into a first sub-period and a second sub-period in response to a first phase control signal and a second phase control signal, wherein the controller respectively outputs a first control signal and a second control signal in the first and second sub-periods according to an energy-saving condition indicated by the reference signal,
wherein the power circuit controlled by the first and second control signals provides a first voltage signal and a second voltage signal in the first and second sub-periods, respectively, to drive the operational amplifier, such that the operational amplifier provides the output voltage signal according to the input voltage signal.

46. The source driver according to claim 45, wherein
the controller respectively outputs a third control signal and a fourth control signal in the first and the second sub-periods according to a normal condition indicated by the reference signal; and
the power circuit controlled by the third and the fourth control signals provides a third voltage signal and a fourth voltage signal in the first and second sub-periods, respectively, to drive the operational amplifier, such that the operational amplifier provides the output voltage signal according to the input voltage signal.

47. An output buffer for providing an output voltage signal in an operation period, the output buffer comprising:
an operational amplifier for providing the output voltage signal according to an input voltage signal; and
a power circuit, coupled to the operational amplifier, for selectively providing a first power voltage or a second power voltage to the operational amplifier according to the input voltage signal.

48. The output buffer according to claim 47, further comprising:
a controller for outputting a first control signal in the operation period according to an energy-saving condition indicated by the input voltage signal, and outputting a second control signal in the operation period according to a normal condition indicated by the input voltage signal,
wherein the power circuit is controlled by the first control signal to provide the first power voltage to drive the operational amplifier, and is controlled by the second control signal to provide the second power voltage to drive the operational amplifier, such that the operational amplifier provides the output voltage signal according to the input voltage signal.

49. The output buffer according to claim 47, further comprising:
a controller for dividing the operation period into a first sub-period and a second sub-period in response to a first phase control signal and a second phase control signal, wherein the controller respectively outputs a first control signal and a second control signal according to an energy-saving condition indicated by the input voltage signal in the first and second sub-periods,
wherein the power circuit controlled by the first and second control signals provides a first voltage signal and a second voltage signal in the first and second sub-periods, respectively, to drive the operational amplifier, such that the operational amplifier provides the output voltage signal according to the input voltage signal.

50. The output buffer according to claim 49, wherein
the controller respectively outputs a third control signal and a fourth control signal in the first and the second sub-periods according to a normal condition indicated by the reference signal; and
the power circuit controlled by the third and the fourth control signals provides a third voltage signal and a fourth voltage signal in the first and second sub-periods, respectively, to drive the operational amplifier, such that the operational amplifier provides the output voltage signal according to the input voltage signal.

51. A source driver for providing a plurality of pixel voltage signals to drive a liquid crystal display panel, the source driver comprising:
a linear buffer comprising a plurality of linear buffer units for respectively storing a plurality of pieces of input pixel data;
a digital-to-analog (D/A) converter comprising a plurality of D/A converting units respectively corresponding to the linear buffer units to respectively convert the pieces of input pixel data into a plurality of analog voltage signals; and
a plurality of output buffers each comprising:
an operational amplifier for providing an output voltage signal according to an input voltage signal; and
a power circuit, coupled to the operational amplifier, for selectively providing a first power voltage or a second power voltage to the operational amplifier according to the input voltage signal.

52. The source driver according to claim 51, further comprising:
a controller for outputting a first control signal according to an energy-saving condition indicated by the input voltage signal in an operation period, and outputting a second control signal according to a normal condition indicated by the input voltage signal in the operation period,
wherein the power circuit is controlled by the first control signal to provide the first power voltage to drive the operational amplifier, and is controlled by the second control signal to provide the second power voltage to drive the operational amplifier, such that the operational amplifier provides the output voltage signal according to the input voltage signal.

53. The source driver according to claim 51, further comprising:
a controller for dividing an operation period into a first sub-period and a second sub-period in response to a first phase control signal and a second phase control signal, wherein the controller respectively outputs a first control signal and a second control signal in the first and second sub-periods according to an energy-saving condition indicated by the input voltage signal,
wherein the power circuit controlled by the first and second control signals provides a first voltage signal and a second voltage signal in the first and second sub-periods, respectively, to drive the operational amplifier, such that the operational amplifier provides the output voltage signal according to the input voltage signal.

54. The source driver according to claim 53, wherein:
the controller respectively outputs a third control signal and a fourth control signal in the first and the second sub-periods according to a normal condition indicated by the reference signal; and
the power circuit controlled by the third and the fourth control signals provides a third voltage signal and a fourth voltage signal in the first and second sub-periods, respectively, to drive the operational amplifier, such that the operational amplifier provides the output voltage signal according to the input voltage signal.

55. A source driver for providing n pixel voltage signals to drive a liquid crystal display panel, n being a natural number greater than 1, the source driver comprising:
a linear buffer comprising n linear buffer units for respectively storing n pieces of input pixel data;
m output buffers for respectively providing m gray-level pixel voltage signals corresponding to m gray levels, wherein m is a natural number greater than 1, and each of the output buffers comprises:
an operational amplifier for providing an output voltage signal according to an input voltage signal; and
a power circuit, coupled to the operational amplifier, for selectively providing a first power voltage or a second power voltage to the operational amplifier according to the input voltage signal; and
a digital-to-analog (D/A) converter comprising n D/A converting units for respectively selecting at least one gray-level pixel voltage from the m gray-level pixel voltage signals as the n pixel voltage signals for output in response to the n pieces of input pixel data.

56. The source driver according to claim 55, further comprising:
a controller for outputting a first control signal according to an energy-saving condition indicated by the input voltage signal in an operation period, and outputting a second control signal according to a normal condition indicated by the input voltage signal in the operation period,
wherein the power circuit is controlled by the first control signal to provide the first power voltage to drive the operational amplifier, and is controlled by the second control signal to provide the second power voltage to drive the operational amplifier, such that the operational amplifier provides the output voltage signal according to the input voltage signal.

57. The source driver according to claim 55, further comprising:
a controller for dividing an operation period into a first sub-period and a second sub-period in response to a first phase control signal and a second phase control signal, wherein the controller respectively outputs a first control signal and a second control signal in the first and second sub-periods according to an energy-saving condition indicated by the input voltage signal,
wherein the power circuit controlled by the first and second control signals provides a first voltage signal and a second voltage signal in the first and second sub-periods, respectively, to drive the operational amplifier, such that the operational amplifier provides the output voltage signal according to the input voltage signal.

58. The source driver according to claim 57, wherein:
the controller respectively outputs a third control signal and a fourth control signal in the first and the second sub-periods according to a normal condition indicated by the reference signal; and
the power circuit controlled by the third and the fourth control signals provides a third voltage signal and a fourth voltage signal in the first and second sub-periods, respectively, to drive the operational amplifier, such that the operational amplifier provides the output voltage signal according to the input voltage signal.
